(19) United States
(12) Patent Application Publication
(10) Pub. No.: US 2011/0260315 A1
(43) Pub. Date: Oct. 27, 2011

(54) POWER BLOCK AND POWER SEMICONDUCTOR MODULE USING SAME

(75) Inventors: Yoshihiro YAMAGUCHI, Tokyo (JP); Seiji Oka, Tokyo (JP); Osamu Usui, Tokyo (JP); Takeshi Oi, Tokyo (JP)

(73) Assignee: MITSUBISHI ELECTRIC CORPORATION, Chiyoda-ku (JP)

(21) Appl. No.: 13/008,470

(22) Filed: Jan. 18, 2011

(30) Foreign Application Priority Data
Apr. 21, 2010 (JP) 2010-097902

(51) Int. Cl. H01L 23/492; H01L 23/02

(52) U.S. Cl. 257/696; 257/737; 257/E23.026; 257/E23.18

(57) ABSTRACT

A power block includes an insulating substrate, a conductive pattern formed on the insulating substrate, a power semiconductor chip bonded onto the conductive pattern by lead-free solder, a plurality of electrodes electrically connected to the power semiconductor chip and extending upwardly away from the insulating substrate, and a transfer molding resin covering the conductive pattern, the lead-free solder, the power semiconductor chip, and the plurality of electrodes, wherein surfaces of the plurality of electrodes are exposed at an outer surface of the transfer molding resin and lie in the same plane as the outer surface, the outer surface being located directly above the conductive pattern.

### BACKGROUND OF THE INVENTION

1. Field of the Invention

The present invention relates to a power block including power semiconductor chips sealed or encapsulated with a transfer molding resin, and to a power semiconductor module using such a power block.

2. Background Art

Power blocks are used to control the current supplied to a load. In a typical construction of a power block, power semiconductor chips, electrodes, etc. are bonded to conductive patterns on an insulating substrate, and these components are encapsulated with a resin as necessary. It should be noted that the power semiconductor chips are, e.g., IGBTs or freewheeling diodes.

In order to protect the environment, SnAgCu- or SnAgCuSb-based lead-free solders are sometimes used instead of lead-containing solders to bond power semiconductor chips and electrodes to conductive patterns. However, devices using lead-free solder are known to have lower temperature cycling resistance than devices using lead-containing solder. One conventional practice to provide sufficient temperature cycling resistance to a structure using lead-free solder is to place it in a mold and encapsulate it by transfer molding. The resulting structure (i.e., a power block) has sufficient temperature cycling resistance, since it is covered with a transfer molding resin.

When a power block is transfer molded, the electrodes of the power block are sandwiched between the upper and lower molds so that these electrodes extend outwardly through and beyond the resin. This means that in resin-transfer-molded power blocks, the electrodes extend parallel to the surface of the insulating substrate.

On the other hand, power blocks manufactured without using transfer molding are typically constructed so that their electrodes extend upwardly from the top surface of the insulating substrate in order to reduce the mounting area. It should be noted that the exposed ends of the electrodes of power blocks are preferably located at such positions that the power blocks can be interchangeable with one another regardless of the way they are produced. However, since power blocks using lead-free solder must be transfer molded, they cannot be constructed so that the electrodes extend upwardly from the top surface of the insulating substrate. Therefore, it has been difficult to ensure interchangeability between transfer-molded power blocks using lead-free solder and power blocks manufactured without using transfer molding. This lack of interchangeability between these power blocks is likely to lead to a lack of interchangeability between the power semiconductor modules containing them.

### SUMMARY OF THE INVENTION

The present invention has been made to solve the above problems. It is, therefore, an object of the present invention to provide a power block which uses lead-free solder and transfer molding resin yet is interchangeable with power blocks which do not use lead-free solder and transfer molding resin. Another object of the present invention is to provide a power semiconductor module using such a power block.

According to one aspect of the present invention, a power block includes an insulating substrate, a conductive pattern formed on the insulating substrate, a power semiconductor chip bonded onto the conductive pattern by lead-free solder, a plurality of electrodes electrically connected to the power semiconductor chip and extending upwardly away from the insulating substrate, and a transfer molding resin covering the conductive pattern, the lead-free solder, the power semiconductor chip, and the plurality of electrodes, wherein surfaces of the plurality of electrodes are exposed at an outer surface of the transfer molding resin and lie in the same plane as the outer surface, the outer surface being located directly above the conductive pattern.

According to another aspect of the present invention, a power semiconductor module includes the above power block, a base plate bonded to the bottom of the power block, and a case covering the power block.

Other and further objects, features and advantages of the invention will appear more fully from the following description.

### BRIEF DESCRIPTION OF THE DRAWINGS

FIG. 1 is a perspective view of a power block of the first embodiment;

FIG. 2 is a plan view of the power block of the first embodiment;

FIG. 3 is a cross-sectional view taken along a dashed line III-III of FIG. 1;

FIG. 4 is cross-sectional view taken along a dashed line IV-IV of FIG. 1;

FIG. 5 is a cross-sectional view of a power semiconductor module according to a second embodiment of the present invention;

FIG. 6 is a perspective view of a power block of the third embodiment;

FIG. 7 is a plan view of the power block of the third embodiment;

FIG. 8 is a cross-sectional view taken along a dashed line VIII-VIII of FIG. 6;

FIG. 9 is a perspective view of the cylindrical conductor;

FIG. 10 is a cross-sectional view taken along a dashed line X-X of FIG. 6;

FIG. 11 is a cross-sectional view taken along a dashed line XI-XI of FIG. 6;

FIG. 12 is a cross-sectional view taken along a dashed line XII-XII of FIG. 6;

FIG. 13 is a perspective view of hexagonal cylindrical conductors which have been substituted for cylindrical conductors of the third embodiment;

FIG. 14 is a perspective view of a U-shaped bent conductor which has been substituted for cylindrical conductors of the third embodiment; and

FIG. 15 is a perspective view of a double U-shaped bent conductor which has been substituted for cylindrical conductors of the third embodiment.

### DETAILED DESCRIPTION OF THE PREFERRED EMBODIMENTS

### First Embodiment

A first embodiment of the present invention will be described with reference to FIGS. 1 to 4. It should be noted that throughout the description of the first embodiment certain of the same or corresponding components are designated by the same reference numerals and described only once. This also applies to the second and third embodiments of the invention subsequently described.

FIG. 1 is a perspective view of a power block 10 of the first embodiment. Many portions of the power block 10 are covered with transfer molding resin 12. The transfer molding resin 12 has a flat plate-like configuration. A collector electrode 14, an emitter electrode 16, and gate electrodes 18 are exposed at the top surface of the transfer molding resin 12. The exposed surfaces of these electrodes lie in the same plane as the top surface of the transfer molding resin 12; that is, these exposed surfaces of the electrodes and the top surface of the transfer molding resin 12 form a single continuous surface. Legs 12a are formed on the bottom surface of the transfer molding resin 12.

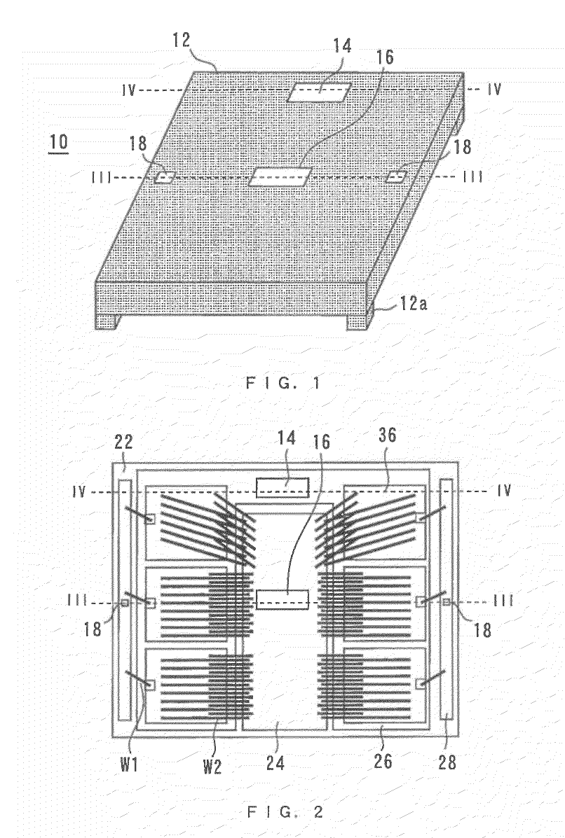

FIG. 2 is a plan view of the power block 10 of the first embodiment. The transfer molding resin 12 is omitted from FIG. 2 to show the internal structure of the power block 10. An insulating substrate 22 is encapsulated inside the power block 10. A conductive pattern 24, a conductive pattern 26, and conductive patterns 28 are formed on the insulating substrate 22. The conductive patterns 24, 26, and 28 are made, e.g., of Al or Cu. The emitter electrode 16 is bonded onto the conductive pattern 24. Power semiconductor chips 36 and the collector electrode 14 are bonded onto the conductive pattern 26. The power semiconductor chips 36 are IGBTs. An emitter and a gate are formed in the top surface of each power semiconductor chip 36, and a collector is formed in the bottom surface. Each gate electrode 18 is bonded onto one of the conductive patterns 28.

The gate of each power semiconductor chip 36 is connected to one of the conductive patterns 28 by an aluminum wire W1, so that the gate is electrically connected to the gate electrode 18 bonded to that conductive pattern 28. Further, the emitter of each power semiconductor chip 36 is connected to the conductive pattern 24 by aluminum wires W2, so that the emitter is electrically connected to the emitter electrode 16. Further, the collector in the bottom surface of each power semiconductor chip 36 is electrically connected to the conductive pattern 26, so that the collector is electrically connected to the collector electrode 14.

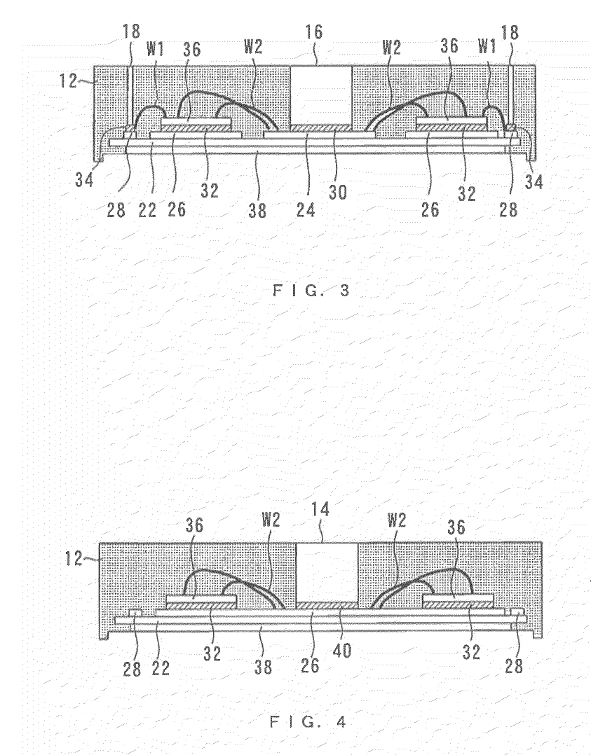

FIG. 3 is a cross-sectional view taken along a dashed line III-III of FIG. 1. This cross-sectional view of the power block 10 includes the emitter electrode 16 and the gate electrodes 18. It should be noted that the dashed line III-III in FIG. 2 corresponds to the dashed line III-III in FIG. 1 and is added to facilitate understanding of the embodiment. The components on the top surface of the insulating substrate 22 will be described with reference to FIG. 3. The conductive patterns 24, 26, and 28 are formed on the insulating substrate 22. The emitter electrode 16 is bonded onto the conductive pattern 24 by lead-free solder 30. The power semiconductor chips 36 are bonded onto the conductive pattern 26 by lead-free solder 32. Each gate electrode 18 is bonded onto one of the conductive patterns 28 by lead-free solder 34. The bottom side of the insulating substrate 22 will now be described. A surface pattern 38 is formed on the bottom surface of the insulating substrate 22 and exposed through the transfer molding resin 12.

FIG. 4 is cross-sectional view taken along a dashed line IV-IV of FIG. 1. This cross-sectional view of the power block 10 includes the collector electrode 14. It should be noted that the dashed line IV-IV in FIG. 2 corresponds to the dashed line IV-IV in FIG. 1. Referring to FIG. 4, the collector electrode 14 is bonded onto the conductive pattern 26 by lead-free solder 40.

The collector electrode 14, the emitter electrode 16, and the gate electrodes 18 are electrically connected to the collectors, emitters, and gates, respectively, of the power semiconductor chips 36, as described with reference with FIGS. 2 to 4. These electrodes may be hereinafter referred to collectively as the power block electrodes. The power block electrodes extend upwardly away from the insulating substrate 22, and are exposed at the outer surface of the transfer molding resin 12 which is located directly above the conductive patterns 24, 26, and 28. The exposed surfaces of the power block electrodes lie in the same plane as that outer surface of the transfer molding resin 12. The power semiconductor chips 36, the lead-free solder 30, 32, 34, and 40, and the conductive patterns 24, 26, and 28 are covered with the transfer molding resin 12. The surfaces of each power block electrode, except for the top surface, are also covered with the transfer molding resin 12.

Thus, in the power block 10 of the first embodiment, the collector electrode 14, the emitter electrode 16, and the gate electrodes 18 are exposed at the outer surface (top surface) of the transfer molding resin 12 which is located directly above the conductive patterns 24, 26, and 28. Therefore, the power block 10 of the first embodiment can be interchangeable with power blocks which do not use transfer molding resin.

As described above, the construction of the power block 10 of the first embodiment allows it to be manufactured using lead-free solder and transfer molding resin so that it has an increased temperature cycling resistance and a reduced impact on the environment yet is interchangeable with power blocks which do not use lead-free solder and transfer molding resin.

### Second Embodiment

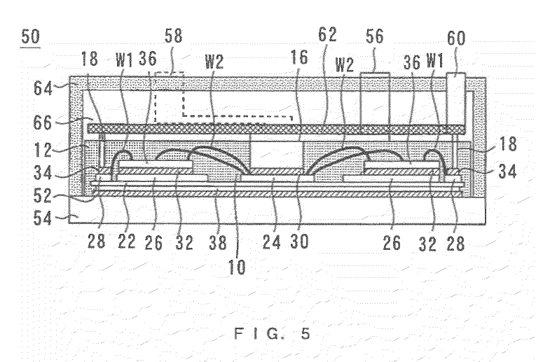

A second embodiment of the present invention will be described with reference to FIG. 5. FIG. 5 is a cross-sectional view of a power semiconductor module 50 according to a second embodiment of the present invention. The power semiconductor module 50 packages or contains the power block 10 of the first embodiment, etc. The cross-section of the module shown in FIG. 5 includes the emitter electrode 16 and the gate electrodes 18. The surface pattern 38 of the power block 10 is bonded to a base plate 54 by lead-free solder 52. The base plate 54 is made of Cu, AlSiC, or Cu—Mo, etc.

A main electrode 56 is connected to the emitter electrode 16 of the power block 10. A main electrode 58 (indicated by a dashed line in FIG. 5) is connected to the collector electrode. The main currents of the power semiconductor chips 36 flow through the main electrodes 56 and 58. A gate signal terminal 60 is connected to the gate electrodes 18. The gate signal terminal 60 is used to supply a gate drive signal to the power semiconductor chips 36. The main electrodes 56 and 58 and the gate signal terminal 60 (which may be hereinafter referred to collectively as the lead-out electrodes) are Ni-plated thin Cu plates. The lead-out electrodes are connected to their respective power block electrodes through a printed board 62 with patterns formed thereon.

The structure described above is covered with a case 64. Specifically, the power block 10, the lead-out electrodes, and the printed board 62 are covered with the case 64. However, a portion of each lead-out electrode is exposed at the top surface of the case 64. The case 64 is fixed to the peripheral portion of the base plate 54; specifically, they are fixed together by screws or silicon rubber. The inside of the case 64 is filled with silicon gel 66.

It is conventional practice to fill the entire inside of a power semiconductor module with expensive, highly reliable silicon gel to insulate the power block. This, however, prevents reductions in the cost of the power semiconductor module. Further, it has been found that gas bubbles may be generated within the silicon gel due to temperature cycling, thereby degrading the reliability of the power semiconductor module. It should be noted that the above gas bubbles originate from the solder used in the power block.

The construction of the power semiconductor module 50 of the second embodiment overcomes the foregoing problems. Specifically, the transfer molding resin 12 covering the power block 10 insulates it. This eliminates the need for expensive silicon gel, thereby allowing a reduction in the cost of the power semiconductor module 50. Further, the solder (lead-free solder) in the power block 10 is covered with the transfer molding resin 12, thereby preventing the generation of gas bubbles in the power semiconductor module. Thus the second embodiment enables the manufacture of highly reliable power semiconductor modules. These power semiconductor modules also have the advantages described in connection with the power block 10 of the first embodiment.

### Third Embodiment

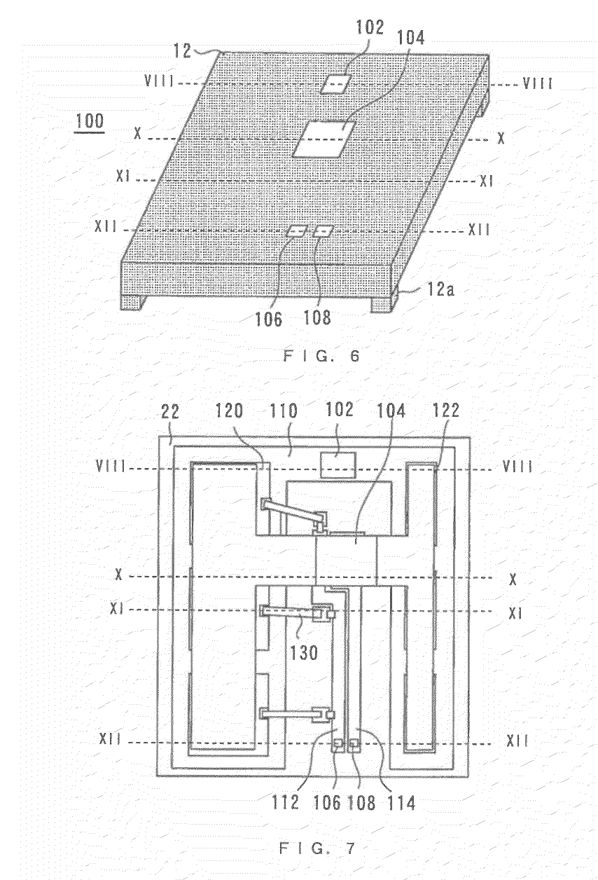

A third embodiment of the present invention will be described with reference to FIGS. 6 to 15. FIG. 6 is a perspective view of a power block 100 of the third embodiment. Many portions of the power block 100 are covered with transfer molding resin 12. A collector electrode 102, an emitter electrode 104, a gate electrode 106, and a sensing electrode 108 are exposed at the top surface of the transfer molding resin 12.

FIG. 7 is a plan view of the power block 100 of the third embodiment. The transfer molding resin 12 is omitted from FIG. 7 to show the internal structure of the power block 100. An insulating substrate 22 is encapsulated inside the power block 100. A conductive pattern 110, a conductive pattern 112, and a conductive pattern 114 are formed on the insulating substrate 22.

Power semiconductor chips 120, power semiconductor chips 122, and the collector electrode 102 are bonded onto the conductive pattern 110. The power semiconductor chips 120 are IGBTs, and the power semiconductor chips 122 are freewheeling diodes. The emitter electrode 104 is bonded onto the power semiconductor chips 120 and 122.

The gate electrode 106 is bonded onto the conductive pattern 112. Further, the gate of each power semiconductor chip 120 is connected to the top surface of the conductive pattern 112 through a bar electrode 130.

The sensing electrode 108 and the emitter electrode 104 are bonded onto the conductive pattern 114. Thus, the power block 100 of the third embodiment uses conductive patterns and electrodes to interconnect components therein and does not use aluminum wires.

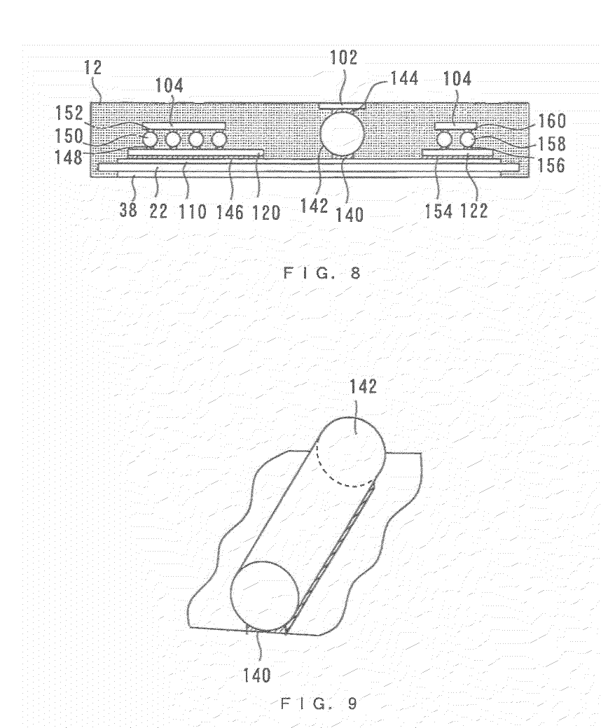

FIG. 8 is a cross-sectional view taken along a dashed line VIII-VIII of FIG. 6. This cross-sectional view includes the collector electrode 102 exposed at the top surface of the transfer molding resin 12. It should be noted that the dashed line VIII-VIII in FIG. 7 corresponds to the dashed line VIII-VIII in FIG. 6 and is added to facilitate understanding of the embodiment. (The other dashed lines in FIG. 7 also correspond to the respective dashed lines in FIG. 6.) A cylindrical conductor 142 is bonded onto the conductive pattern 110 on the insulating substrate 22 by lead-free solder 140. The collector electrode 102 is bonded onto the cylindrical conductor 142 by lead-free solder 144.

The cylindrical conductor 142 will now be described with reference to FIG. 9. FIG. 9 is a perspective view of the cylindrical conductor 142. The cylindrical conductor 142 is of a hollow circular cylindrical shape and has the lead-free solder 140 and 144 applied to its outer cylindrical surface. The cylindrical conductor 142 is made of such a material that it deforms when pressure is applied to its outer cylindrical side.

Referring back to FIG. 8, the power semiconductor chips 120 are bonded onto the conductive pattern 110 by lead-free solder 146. Cylindrical conductors 150 are bonded onto the power semiconductor chips 120 by lead-free solder 148. The emitter electrode 104 is bonded onto the cylindrical conductors 150 by lead-free solder 152.

Likewise, the power semiconductor chips 122 are bonded onto the conductive pattern 110 by lead-free solder 154. Cylindrical conductors 158 are bonded onto the power semiconductor chips 122 by lead-free solder 156. The emitter electrode 104 is bonded onto the cylindrical conductors 158 by lead-free solder 160.

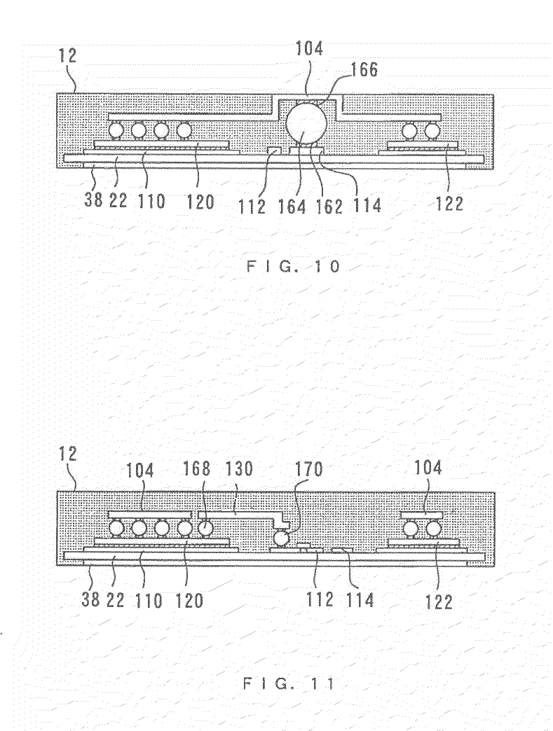

FIG. 10 is a cross-sectional view taken along a dashed line X-X of FIG. 6. This cross-sectional view includes the emitter electrode 104 exposed at the top surface of the transfer molding resin 12. A cylindrical conductor 164 is bonded onto the conductive pattern 114 by lead-free solder 162. The emitter electrode 104 is bonded onto the cylindrical conductor 164 by lead-free solder 166. The other cylindrical conductors shown in FIG. 10 have been described above with reference to FIG. 8.

FIG. 11 is a cross-sectional view taken along a dashed line XI-XI of FIG. 6. This cross-sectional view includes a bar electrode 130 interconnecting the gate of a power semiconductor chip 120 and the conductive pattern 112. The bar electrode 130 is bonded onto a cylindrical conductor 168 and a cylindrical conductor 170. The other cylindrical conductors shown in FIG. 11 have been described above with reference to FIG. 8.

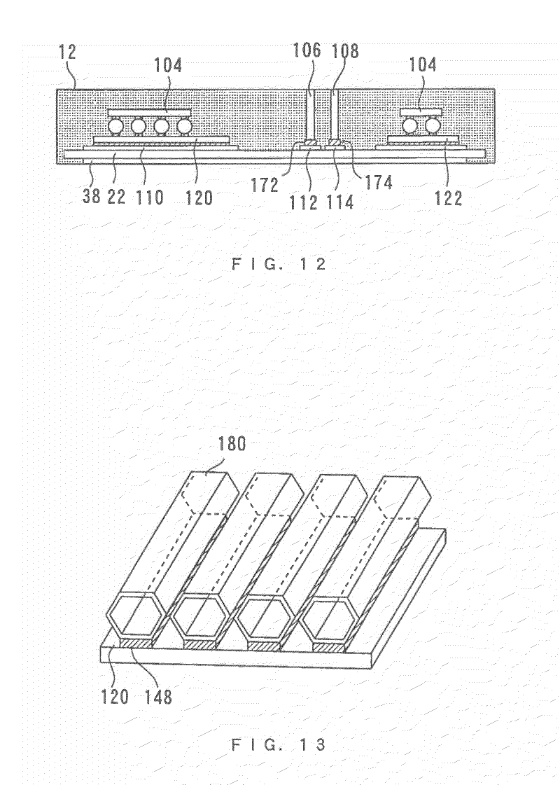

FIG. 12 is a cross-sectional view taken along a dashed line XII-XII of FIG. 6. This cross-sectional view includes the gate electrode 106 and the sensing electrode 108 exposed at the top surface of the transfer molding resin 12. The gate electrode 106 is bonded onto the conductive pattern 112 by lead-free solder 172. The sensing electrode 108 is bonded onto the conductive pattern 114 by lead-free solder 174. The cylindrical conductors shown in FIG. 12 have been described above with reference to FIG. 8. As described above, the power block 100 uses conductive patterns and electrodes to interconnect components therein without using aluminum wires. Further, cylindrical conductors are bonded to the bottoms of the collector electrode 102 and the emitter electrode 104.

In the transfer molding process of a power block, the electrodes could be pressed against the power semiconductor chips and the insulating substrate by the applied force to such an extent that the chips and substrate are damaged. The third embodiment overcomes this problem. In the power block 100 of the third embodiment, the cylindrical conductors 142, 150, 158, and 164 and other cylindrical conductors are bonded to the bottom of the collector electrode 102 or the emitter electrode 104. This construction can reduce the damage to the power semiconductor chips 120 and 122 and the insulating substrate 22 due to the pressure applied during the transfer molding process.

The power semiconductor chips of different types of power blocks often have different thicknesses. This means that the transfer molded structures of such power blocks which accommodate the power semiconductor chips also have different thicknesses and hence require different sets of manufacturing molds, resulting in increased manufacturing cost. The construction of the power block 100 of the third embodiment overcomes this problem by allowing different types of power blocks to be manufactured using only a single set of molds. Specifically, the cylindrical conductors in the power block 100 are deformed so as to compensate for variations in the thickness of the power semiconductor chips, allowing the transfer molded structure to have the same thickness regardless of the thickness of the power semiconductor chips used. This eliminates the need for a different set of molds for each power semiconductor chip having a different thickness, resulting in reduced manufacturing cost.

The cylindrical conductors of the third embodiment may be of any suitable shape and material which allow them to act as buffering conductors to reduce damage to the power semiconductor chips or the insulating substrate during the transfer molding process. FIGS. 13, 14, and 15 show variations of the cylindrical conductors of the third embodiment.

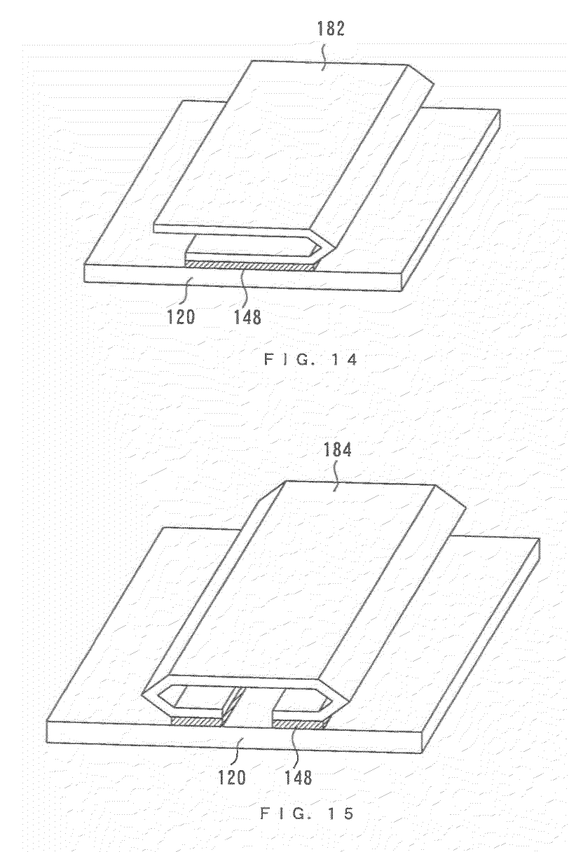

FIG. 13 is a perspective view of hexagonal cylindrical conductors 180 which have been substituted for cylindrical conductors of the third embodiment. FIG. 14 is a perspective view of a U-shaped bent conductor 182 which has been substituted for cylindrical conductors of the third embodiment. FIG. 15 is a perspective view of a double U-shaped bent conductor 184 which has been substituted for cylindrical conductors of the third embodiment.

Thus the present invention provides a power block which uses lead-free solder and transfer molding resin yet is interchangeable with power blocks which do not use lead-free solder and transfer molding resin, and also provides a power semiconductor module using such a power block.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2010-097902, filed on Apr. 21, 2010 including specification, claims, drawings and summary, on which the Convention priority of the present application is based, are incorporated herein by reference in its entirety.

What is claimed is:

1. A power block comprising:
an insulating substrate;
a conductive pattern formed on said insulating substrate;
a power semiconductor chip bonded onto said conductive pattern by lead-free solder;
a plurality of electrodes electrically connected to said power semiconductor chip and extending upwardly away from said insulating substrate; and
a transfer molding resin covering said conductive pattern, said lead-free solder, said power semiconductor chip, and said plurality of electrodes;
wherein surfaces of said plurality of electrodes are exposed at an outer surface of said transfer molding resin and lie in the same plane as said outer surface, said outer surface being located directly above said conductive pattern.

2. The power block according to claim 1, further comprising:
a buffering conductor bonded onto said power semiconductor chip by lead-free solder;
wherein at least one of said plurality of electrodes is bonded onto said buffering conductor by lead-free solder; and
wherein said buffering conductor is of a shape and material which allow said buffering conductor to be deformed so as to change the distance between said power semiconductor chip and said at least one of said plurality of electrodes;

3. The power block according to claim 2, wherein said buffering conductor is a cylindrical conductor.

4. The power block according to claim 2, wherein said buffering conductor is a hexagonal cylindrical conductor.

5. The power block according to claim 2, wherein said buffering conductor is a U-shaped bent conductor.

6. The power block according to claim 2, wherein said buffering conductor is a double U-shaped bent conductor.

7. A power semiconductor module comprising:
the power block of claim 1;
a base plate bonded to the bottom of said power block; and
a case covering said power block.
